(19) United States
(12) Patent Application Publication
(10) Pub. No.: US 2017/0092818 A1
(43) Pub. Date: Mar. 30, 2017

(54) LIGHT-EMITTING ELEMENT MOUNTING SUBSTRATE AND LIGHT-EMITTING PACKAGE USING THE SAME, FABRICATING METHOD OF THE LIGHT-EMITTING ELEMENT MOUNTING SUBSTRATE AND FABRICATING METHOD OF LIGHT-EMITTING DEVICE USING THE SAME

(71) Applicant: SAMSUNG ELECTRONICS CO., LTD., Suwon-si (KR)

(72) Inventor: Jung-Hoon KIM, Hwaseong-si (KR)

(73) Assignee: SAMSUNG ELECTRONICS CO., LTD., Suwon-si (KR)

(21) Appl. No.: 15/273,993

(22) Filed: Sep. 23, 2016

(30) Foreign Application Priority Data
Sep. 24, 2015 (KR) 10-2015-0135161

(51) Int. Cl. H01L 33/48; H01L 33/62; H01L 33/60

(52) U.S. Cl. CPC H01L 33/486; H01L 33/60; H01L 33/62

(57) ABSTRACT

There is provided a light-emitting element mounting substrate which includes: an insulative base plate including a first surface and a second surface opposed to each other; a first conductive pad formed on the first surface of the insulative base plate; a second conductive pad formed on the first surface of the insulative base plate, and being separated from the first conductive pad; a first through hole and a second through hole penetrating through the insulative base plate and being separated from each other; a first through conduit filling the first through hole and being adjoined with the first conductive pad; and a second through conduit filling the second through hole and being adjoined with the second conductive pad, wherein, with reference to the first surface of the insulative base plate, a sum of an area of the first through conduit and an area of the second through conduit is between 20% and 80% of an area of the first surface of the insulative base plate.

### CROSS-REFERENCE TO THE RELATED APPLICATION

This application claims priority from Korean Patent Application No. 10-2015-0135161 filed on Sep. 24, 2015 the disclosure of which is incorporated herein by reference in its entirety.

### BACKGROUND

1. Field

The present disclosure relates to a light-emitting element mounting substrate and a light-emitting package using the same, a fabricating method of the light-emitting element mounting substrate and a fabricating method of a light-emitting device using the same.

2. Description of the Related Art

A light-emitting diode (LED) is a device of which matters included therein emit light by using electric energy. It converts the energy generated from recombination of electrons and electron holes of an attached semiconductor into light and emits the same. Currently, such LED is widely used as a lighting device, a display device and a light source, and is subject to continuous development.

Particularly, with the commercialization of mobile phone keypads, vehicle turning signal lamps, camera flashes, and so on using gallium nitride (GaN)-based light-emitting diodes for which development and use have been expedited recently, development of the general lighting using light-emitting diodes is recently gaining increased attention. The examples such as backlight units for large-size televisions (TVs), automobile headlights, general lighting and applied products thereof indicate gradually shifting tendency of use of the light-emitting element toward large-size, high-output, and high-efficiency products. Accordingly, a method for improving light extraction efficiency of a light-emitting element for use thereof, and also a method for reducing a size and improving heat dissipation of a light-emitting device including the light-emitting element, are necessary.

### SUMMARY

A technical object is to provide a light-emitting element mounting substrate which can improve heat dissipation and also reduce product unit costs.

Another technical object is to provide a light-emitting package which can reduce size thereof by use of the light-emitting element mounting substrate.

Yet another technical object is to provide a fabricating method of a light-emitting element mounting substrate which can improve heat dissipation and also reduce product unit costs.

Yet another technical object is to provide a fabricating method of a light-emitting package which can reduce size thereof by use of the light-emitting element mounting substrate.

The objectives that are intended to be addressed by the exemplary embodiments are not limited to those mentioned above, and other objectives that are not mentioned above can be clearly understood to those skilled in the art based on the description provided below.

According to an aspect of an exemplary embodiment, there is provided a light-emitting element mounting substrate which may include: an insulative base plate including a first surface and a second surface opposed to each other; a first conductive pad formed on the first surface of the insulative base plate; a second conductive pad formed on the first surface of the insulative base plate, and being separated from the first conductive pad; a first through hole and a second through hole penetrating through the insulative base plate and being separated from each other; a first through conduit filling the first through hole and being adjoined with the first conductive pad; and a second through conduit filling the second through hole and being adjoined with the second conductive pad, wherein, with reference to the first surface of the insulative base plate, a sum of an area of the first through conduit and an area of the second through conduit is between 20% and 80% of an area of the first surface of the insulative base plate.

In some embodiments of the present inventive concept, the light-emitting element mounting substrate may further comprise an insulative reflective pattern formed on the first surface and surrounding a sidewall of the first conductive pad and a sidewall of the second conductive pad.

In some embodiments of the present inventive concept, the insulative reflective pattern includes a titanium dioxide (TiO₂).

In some embodiments of the present inventive concept, the light-emitting element mounting substrate may further comprise a first conductive reflective film on the first conductive pad, and a second conductive reflective film on the second conductive pad.

In some embodiments of the present inventive concept, the first conductive reflective film is formed on an upper surface and a sidewall of the first conductive pad, and the second conductive reflective film is formed on an upper surface and a sidewall of the second conductive pad.

In some embodiments of the present inventive concept, the first conductive reflective film is formed on an upper surface of the first conductive pad, and not formed on a sidewall of the first conductive pad, and the second conductive reflective film is formed on an upper surface of the second conductive pad and not formed on a sidewall of the second conductive pad.

In some embodiments of the present inventive concept, the first conductive pad and the second conductive pad each includes a portion extending along the first surface.

In some embodiments of the present inventive concept, the first through conduit and the second through conduit each may not include a portion extending along the second surface.

In some embodiments of the present inventive concept, the first through conduit and the second through conduit each may include a first protrusion and a second protrusion protruding from the second surface, respectively, and a height of the first protrusion and a height of the second protrusion are smaller than a thickness of the insulative base plate.

According to an aspect of an exemplary embodiment, there is provided a light-emitting element mounting substrate which may include: an insulative base plate including a first through hole and a second through hole which are separated from each other; an insulative reflective pattern formed on the insulative base plate, contacting the insulative base plate, and comprising a first opening and a second opening which are separated from each other; a first wire including a first conductive pad filling the first opening, and a first through conduit filling the first through hole; and a second wire including a second conductive pad filling the second opening, and a second through conduit filling the second through hole.

In some embodiments of the present inventive concept, a width of the first conductive pad is greater than a width of the first through conduit, and a width of the second conductive pad is greater than a width of the second through conduit, and the first conductive pad entirely overlaps the first through conduit, and the second conductive pad entirely overlaps the second through conduit.

In some embodiments of the present inventive concept, the light-emitting element mounting substrate may further comprise a first conductive reflective film formed on an upper surface of the first conductive pad, and a second conductive reflective film formed on an upper surface of the second conductive pad.

In some embodiments of the present inventive concept, the first conductive reflective film extends on a sidewall of the first conductive pad, and the second conductive reflective film extends on a sidewall of the second conductive pad.

In some embodiments of the present inventive concept, with reference to the first surface of the insulative base plate, a sum of an area of the first through conduit and an area of the second through conduit is between 20% and 80% of an area of the insulative base plate.

In some embodiments of the present inventive concept, the insulative reflective pattern comprises a titanium dioxide (TiO₂).

According to an aspect of an exemplary embodiment, there is provided a light-emitting element mounting substrate which may include: an insulative base plate including first and second through holes penetrating through the insulative base plate from top to bottom surfaces thereof; and first and second conductive wires insulated from each other and respectively inserted in the first and second through holes of the insulative base plate, wherein the first and second conductive wires are protruded from the top and bottom surfaces of the insulative base plate such that a thickness of the first and second wires is greater than a thickness of the insulative base plate, and wherein a width of each of the first and second conductive wires at a portion which is protruded from the top surface of the insulative base plate is greater than a width of each of the first and second conductive wires at a portion which is inserted in each of the first and second through holes, respectively.

The width of each of the first and second conductive wires at the portion which is protruded from the top surface of the insulative base plate is greater than a width of each of the first and second conductive wires at a portion which is protruded from the bottom surface of the insulative base plate, respectively

Each of the first and second through holes has a greater width at the bottom surface of the insulative base plate than the top surface of the insulative base plate

Side surfaces of the first and second conductive wires protruded from the top surface of the insulative base plate are encompassed by an insulative reflective pattern including a titanium dioxide (TiO₂).

Top surfaces of the first and second conductive wires protruded from the top surface of the insulative base plate are coated by first and second conductive reflective films, respectively, and each of the first and second conductive reflective films includes at least one aluminum (Al), silver (Ag), palladium (Pd), rhodium (Rh), and platinum (Pt).

### BRIEF DESCRIPTION OF THE DRAWINGS

The above and other objects, features and advantages of the exemplary embodiments will become more apparent to those of ordinary skill in the art by describing in detail exemplary embodiments thereof with reference to the accompanying drawings, in which:

FIG. 1 is a top view provided to explain a light-emitting element mounting substrate according to some exemplary embodiments;

FIG. 2 is a cross sectional view taken on line A-A of FIG. 1;

FIG. 3 is a view provided to explain a light-emitting element mounting substrate according to some exemplary embodiments;

FIG. 4 is a view provided to explain a light-emitting element mounting substrate according to some exemplary embodiments;

FIG. 5 is a top view provided to explain a light-emitting package according to some exemplary embodiments;

FIG. 6 is a cross sectional view taken on line B-B of FIG. 5;

FIG. 7 is a view provided to explain a light-emitting package according to some exemplary embodiments;

FIG. 8 is a view provided to explain a light-emitting package according to some exemplary embodiments;

FIGS. 9 to 14 are views illustrating intermediate stages of fabrication, provided to explain a fabricating method of a light-emitting element mounting substrate according to some exemplary embodiments;

FIG. 15 is a view illustrating intermediate stages of fabrication, provided to explain a fabricating method of a light-emitting element mounting substrate according to some exemplary embodiments;

FIG. 16 explains an example of applying a light-emitting package to a lighting apparatus according to an exemplary embodiment; and

FIG. 17 represents an example of applying a semiconductor light-emitting element to a head lamp according to an exemplary embodiment.

### DETAILED DESCRIPTION

Advantages and features of the present inventive concept and methods of accomplishing the same may be understood more readily by reference to the following detailed description of exemplary embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the inventive concept to those skilled in the art, and the present inventive concept will only be defined by the appended claims. In the drawings, the thickness of layers and regions are exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept.

The use of the terms “a” and “an” and “the” and similar referents in the context of describing the exemplary embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this inventive concept belongs. It is noted that the use of any and all examples, or exemplary terms provided herein is intended merely to better illuminate the inventive concept and is not a limitation on the scope of the inventive concept unless otherwise specified. Further, unless defined otherwise, all terms defined in generally used dictionaries may not be overly interpreted.

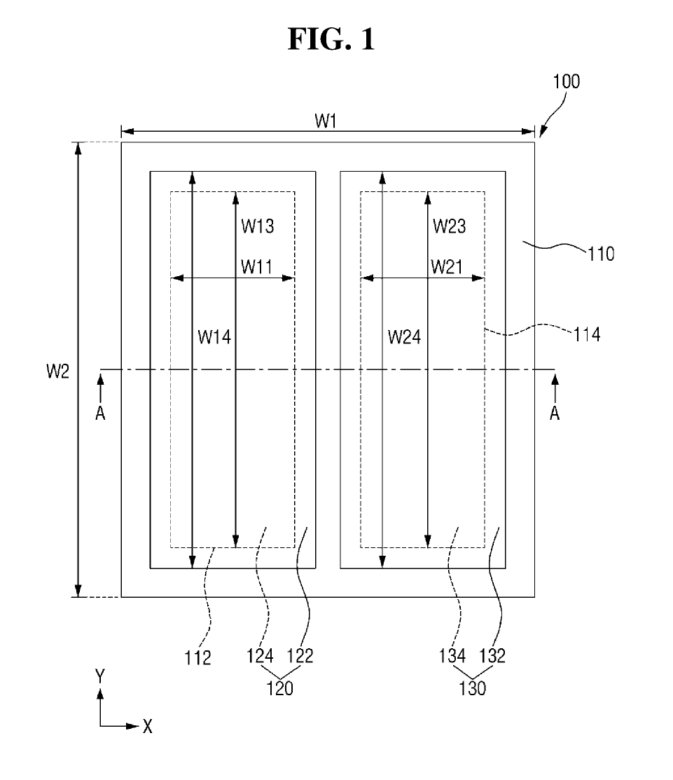

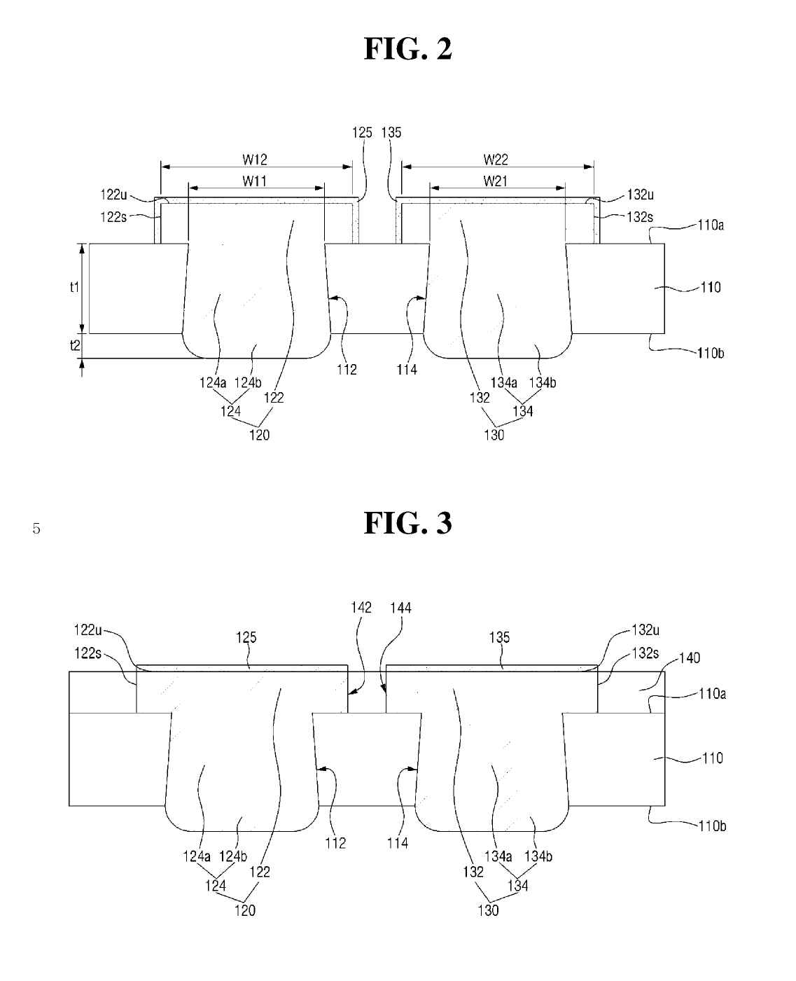

Hereinbelow, a light-emitting element mounting substrate according to some exemplary embodiments will be explained with reference to FIGS. 1 and 2.

FIG. 1 is a top view provided to explain a light-emitting element mounting substrate according to some exemplary embodiments. FIG. 2 is a cross sectional view taken on line A-A of FIG. 1. For convenience of explanation, FIG. 1 skips illustration of first and second conductive reflective films 125, 135.

Referring to FIGS. 1 and 2, a light-emitting element mounting substrate 100 according to some exemplary embodiments may include an insulative base plate 110, a first wire 120 and a second wire 130.

The insulative base plate 110 may include a first surface 110a and a second surface 110b opposed to each other. The insulative base plate 110 may have flexibility, for example, but not limited thereto.

The insulative base plate 110 may include a first through hole 112 and a second through hole 114 which are separated from each other. The first through hole 112 and the second through hole 114 extend from the first surface 110a of the insulative base plate to the second surface 110b of the insulative base plate 110, or from the second surface 110b of the insulative base plate 110 to the first surface 110a of the insulative base plate 110.

As illustrated in FIG. 2, the sidewall of the first through hole 112 and the sidewall of the second through hole 114 may include inclined surfaces such that the first and second through holes 112, 114 at the second surface 110b have a greater width at the second surface 110b than at the first surface 110a, but this is only for illustrative purpose, and the embodiments are not limited thereto.

The insulative base plate 110 may be a single layer. The insulative base plate 110 may not have a configuration in which a plurality of films are stacked on one another. The insulative base plate 110 may or may not include an adhesive film, etc. formed on the first surface 110a and/or the second surface 110b.

The insulative base plate 110 may be a plastic plate such as, for example, polyimide, polyamide-imide, polyethylene naphthalate, epoxy, polyethylene terephthalate (PET), polymethyl methacrylate (PMMA), polycarbonate (PC), polyethersulfone (PES), polyester, aramid, and so on.

In describing the light-emitting element mounting substrate 100 according to some exemplary embodiments, it is assumed that the insulative base plate 110 is a polyimide plastic plate.

The first wire 120 may include a first conductive pad 122 and a first through conduit 124. The first conductive pad 122 and the first through conduit 124 may be directly connected.

As illustrated in FIG. 1, the first conductive pad 122 and the first through conduit 124 may have a square shape in a plan view of the light-emitting element mounting substrate, but this is only for illustrative purpose, and embodiments are not limited thereto. Accordingly, the first conductive pad 122 may have a polygonal shape other than square, or may have a circular shape.

The first conductive pad 122 may be formed on the first surface 110a of the insulative base plate 110. The first conductive pad 122 may contact the insulative base plate 110. That is, no other insertion layer may be interposed between the first conductive pad 122 and the insulative base plate 110.

The first conductive pad 122 may include a portion extending along the first surface 110a of the insulative base plate 110. That is, a portion of the first conductive pad 122 may overlap with the first surface 110a of the insulative base plate 110.

The first through conduit 124 may be formed within the insulative base plate 110. The first through conduit 124 may fill the first through hole 112.

The first through conduit 124 may include a first portion 124a formed within the insulative base plate 110, and a second portion 124b protruding from the second surface 110b of the insulative base plate 110. In other words, along a thickness direction of the insulative base plate 110, the thickness t1 of the insulative base plate 110 may be smaller than the thickness t1+t2 of the first through conduit 124.

Additionally, the thickness t2 of the second portion 124b of the first through conduit protruding from the second surface 110b of the insulative base plate 110 is smaller than the thickness t1 of the insulative base plate 110.

While a portion of the first through conduit 124 may protrude farther than the second surface 110b of the insulative base plate 110, the first through conduit 124 may not include a portion that extends along the second surface 110b of the insulative base plate 110.

The first wire 120 may not include a conductive line or pad extending along the second surface 110b of the insulative base plate 110. That is, a conductive film such as the first conductive pad 122 may not be formed on the second surface 110b of the insulative base plate 110.

The second wire 130 may include a second conductive pad 132 and a second through conduit 134. The second conductive pad 132 and the second through conduit 134 may be directly connected.

The second conductive pad 132 may be formed on the first surface 110a of the insulative base plate 110. The second conductive pad 132 may contact the insulative base plate 110. That is, no other insertion layer may be interposed between the second conductive pad 132 and the insulative base plate 110.

The second conductive pad 132 may include a portion extending along the first surface 110a of the insulative base plate 110. That is, a portion of the second conductive pad 132 may overlap with the first surface 110a of the insulative base plate 110.

The second through conduit 134 may be formed within the insulative base plate 110. The second through conduit 134 may fill the second through hole 114.

The second through conduit 134 may include a first portion 134a formed within the insulative base plate 110, and a second portion 134b protruding from the second surface 110b of the insulative base plate 110. While a portion of the second through conduit 134 may protrude farther than the second surface 110b of the insulative base plate 110, the second through conduit 134 may not include a portion that extends along the second surface 110b of the insulative base plate 110.

Like the first through conduit 124, the thickness of the second portion 134b of the second through conduit protruding from the second surface 110b of the insulative base plate 110 is smaller than the thickness t1 of the insulative base plate 110.

The second wire 130 may not include a conductive line or pad extending along the second surface 110b of the insulative base plate 110.

The second conductive pad 132 is separated from the first conductive pad 122, and the second through conduit 134 is separated from the first through conduit 124. That is, the first wire 120 and the second wire 130 are not connected, electrically and physically.

The first conductive pad 122 and the second conductive pad 132 may include the same material. For example, the first conductive pad 122 and the second conductive pad 132 may include copper (Cu) or copper alloy, but not limited thereto.

The first through conduit 124 and the second through conduit 134 may include the same material. For example, the first through conduit 124 and the second conductive conduit 134 may include copper (Cu) or copper alloy, but not limited thereto.

The first conductive pad 122 and the first through conduit 124 may include the same material, or different materials.

In the light-emitting element mounting substrate 100 according to some exemplary embodiments, there may be two wires that include through conduits penetrating through the insulative base plate 110.

The first conductive reflective film 125 may be formed on the first wire 120. More specifically, the first conductive reflective film 125 may be formed on the first conductive pad 122.

The first conductive reflective film 125 may be formed on a sidewall 122s and an upper surface 122u of the first conductive pad 122. The first conductive reflective film 125 may contact the first conductive pad 122.

The second conductive reflective film 135 may be formed on the second wire 130. More specifically, the second conductive reflective film 135 may be formed on the second conductive pad 132.

The second conductive reflective film 135 may be formed on a sidewall 132s and an upper surface 132u of the second conductive pad. The second conductive reflective film 135 may contact the second conductive pad 132.

The first conductive reflective film 125 and the second conductive reflective film 135 may each include a metal. The first conductive reflective film 125 and the second conductive reflective film 135 may each include at least one of, for example, aluminum (Al), silver (Ag), palladium (Pd), rhodium (Rh), and platinum (Pt).

With reference to the first surface 110a of the insulative base plate 110, the width W12 of the first conductive pad 122 in a first direction X is greater than the width W11 of the first through conduit 124 in the first direction X. Further, the width W14 of the first conductive pad 122 in a second direction Y is greater than the width W13 of the first through conduit 124 in the second direction Y.

That is, the first conductive pad 122 has a greater width than the first through conduit 124 in the first direction X and in the second direction Y. The first conductive pad 122 entirely overlaps the first through conduit 124.

The first conductive pad 122 may extend along the first surface 110a of the insulative base plate 110 by the width difference between the first conductive pad 122 and the first through conduit 124.

Likewise, with reference to the first surface 110a of the insulative base plate 110, the width W22 of the second conductive pad 132 in the first direction X is greater than the width W21 of the second through conduit 134 in the first direction X. Further, the width W24 of the second conductive pad 132 in a second direction Y is greater than the width W23 of the second through conduit 134 in the second direction Y.

The second conductive pad 132 has a greater width than the second through conduit 134 in the first direction X and in the second direction Y. The second conductive pad 132 entirely overlaps the second through conduit 134.

With reference to the first surface 110a of the insulative base plate 110, the sum of the cross sectional area W12×W14 of the first conductive pad 122 and the cross sectional area W22×W24 of the second conductive pad 132 may be between 50% and 90% of the area W1×W2 of the first surface 110a of the insulative base plate 110.

For example, as the area W1×W2 of the first surface 110a of the insulative base plate 110 varies, the sum of the cross sectional area W12×W14 of the first conductive pad 122 and the cross sectional area W22×W24 of the second conductive pad 132 may vary. More specifically, as the area W1×W2 of the first surface 110a of the insulative base plate 110 increases, the sum of the cross sectional area W12×W14 of the first conductive pad 122 and the cross sectional area W22×W24 of the second conductive pad 132 may increase.

Further, with reference to the first surface 110a of the insulative base plate 110, the sum of the cross sectional area W11×W13 of the first conductive pad 124 and the cross sectional area W21×W23 of the second conductive pad 134 may be between 20% and 80% of the area W1×W2 of the first surface 110a of the insulative base plate 110.

For example, as the area W1×W2 of the first surface 110a of the insulative base plate 110 increases, the sum of the cross sectional area W11×W13 of the first conductive pad 124 and the cross sectional area W21×W23 of the second conductive pad 134 may increase.

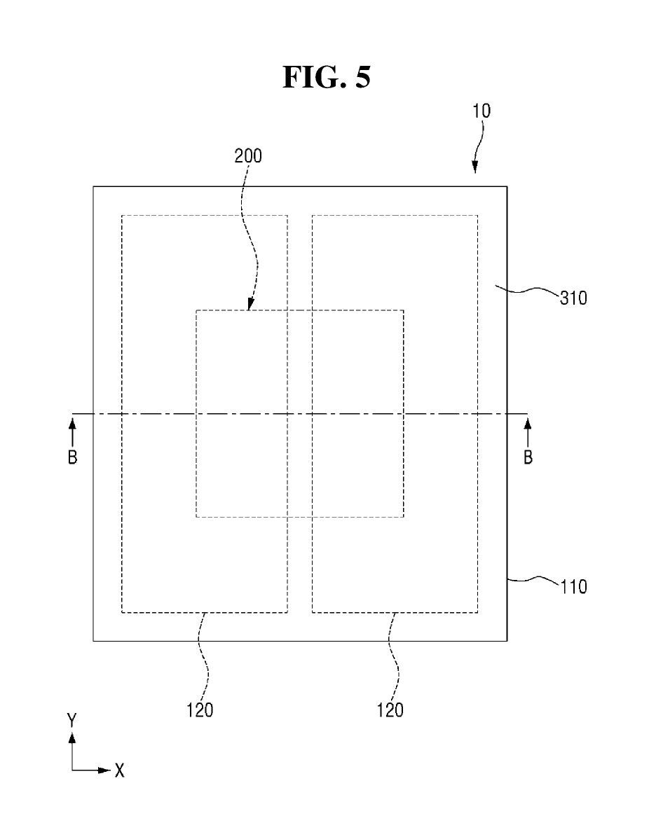

By increasing the ratio of the sum of the areas of the first through conduit 124 and the second through conduit 134 to the area of the insulative base plate 110, it is possible to facilitate the release of heat generated from the light-emitting element mounting substrate 100 and the light-emitting element 200 (see FIG. 5) mounted on the light-emitting element mounting substrate 100.

FIG. 3 is a view provided to explain a light-emitting element mounting substrate according to some exemplary embodiments. For convenience of explanation, differences from the exemplary embodiments explained above with reference to FIGS. 1 and 2 will be mainly explained below. For reference, FIG. 3 is a cross sectional view taken on line A-A of FIG. 1.

Referring to FIG. 3, a light-emitting element mounting substrate 100 according to some exemplary embodiments may additionally include an insulative reflective pattern 140.

An insulative reflective pattern 140 may be formed on the first surface 110a of the insulative base plate 110. The insulative reflective pattern 140 may contact the insulative base plate 110.

The insulative reflective pattern 140 may include a first opening 142 and a second opening 144 which are separated from each other.

The first conductive pad 122 may fill the first opening 142, and the second conductive pad 132 may fill the second opening 144. The insulative reflective pattern 140 may surround the sidewall 122s of the first conductive pad and the sidewall 132s of the second conductive pad formed on the first surface 110a of the insulative base plate 110.

Since the first conductive pad 122 fills the first opening 142, the first opening 142 may have a greater width than the first through hole 112 in the first direction X and in the second direction Y. Further, since the second conductive pad 132 fills the second opening 144, the second opening 144 may have a greater width than the second through hole 114 in the first direction X and in the second direction Y.

That is, the first opening 142 may entirely expose the first through hole 112, and the second opening 144 may entirely expose the second through hole 114.

The insulative reflective pattern 140 may include a highly reflective material. The insulative reflective pattern 140 may include titanium dioxide (TiO₂), for example.

As illustrated in FIG. 3, the upper surface of the insulative reflective pattern 140, the upper surface 122u of the first conductive pad, and the upper surface 132u of the second conductive pad may form a same plane, although exemplary embodiments are not limited thereto.

The first conductive reflective film 125 is formed on the upper surface 122u of the first conductive pad, but not formed on the sidewall 122s of the first conductive pad. Likewise, the second conductive reflective film 135 is formed on the upper surface 132u of the second conductive pad, but not formed on the sidewall 132s of the second conductive pad.

The sidewall 122s of the first conductive pad and the sidewall 132s of the second conductive pad may each be adjoined with the insulative reflective pattern 140.

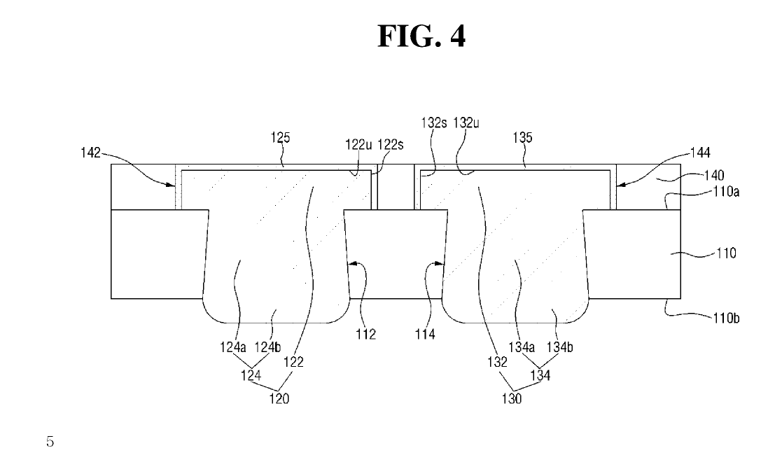

FIG. 4 is a view provided to explain a light-emitting element mounting substrate according to some exemplary embodiments. For convenience of explanation, differences that are not explained above with reference to FIG. 3 will be mainly explained below.

Referring to FIG. 4, in the light-emitting element mounting substrate 100 according to some exemplary embodiments, the first conductive reflective film 125 may extend on the sidewall 122s of the first conductive pad 122, and the second conductive reflective film 135 may extend on the sidewall 132s of the second conductive pad 132.

The insulative reflective pattern 140 may be adjoined with the first conductive reflective film 125 formed on the sidewall 122s of the first conductive pad, and the second conductive reflective film 135 formed on the sidewall 132s of the second conductive pad.

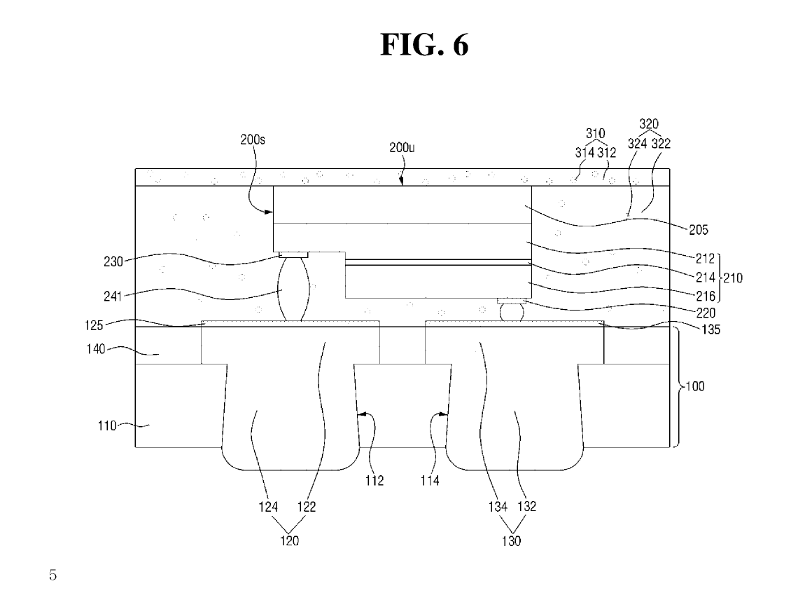

FIG. 5 is a top view provided to explain a light-emitting package according to some exemplary embodiments. FIG. 6 is a cross sectional view taken on line B-B of FIG. 5.

For reference, while FIG. 6 illustrates a light-emitting element mounting substrate 100 based on the light-emitting element mounting substrate described with reference to FIG. 3, this is only for illustrative purpose and the exemplary embodiments are not limited thereto. Accordingly, the light-emitting element mounting substrate 100 illustrated in FIG. 6 may well be the light-emitting element mounting substrate illustrated in one of FIGS. 2 through 4.

Additionally, the light-emitting element mounting substrate 100 will not be described below, since it would overlap with the description provided above with reference to FIGS. 1 to 4.

Referring to FIGS. 5 and 6, a light-emitting package 10 according to some exemplary embodiments may include a light-emitting element mounting substrate 100, a light-emitting element 200, a first fluorescent layer 310 and a second fluorescent layer 320.

The light-emitting element 200 may be mounted on the light-emitting element mounting substrate 100. More specifically, the light-emitting element 200 may be mounted on the first surface 110a of the insulative base plate 110 where the first conductive pad 122 and the second conductive pad 132 are formed. The light-emitting element 200 may be electrically connected with the first wire 120 and the second wire 130.

The light-emitting element 200 may include a substrate 205, a light-emitting structure 210, a first electrode 230, and a second electrode 220.

The substrate 205 may be provided as a substrate for the purpose of semiconductor growth, and may use an insulative conductive semiconductor material such as, for example, sapphire, SiC, MgAl₂O₄, MgO, LiAlO₂, LiGaO₂, GaN, and so on. For example, sapphire is a crystal structure having hexa-rhombo (R3c) type symmetry, in which the lattice constants in a c-axis direction and in an a-axis direction are 13.001 Å and 4.758 Å, respectively, and it includes a C-plane (0001), an A-plane (11-20), and an R-plane (1-102), and so on. In the above example, the C-plane allows relatively easier growth of a nitride membrane and is stable at high temperature, and thus is mainly used as the substrate for nitride growth.

Meanwhile, although not illustrated, the substrate 205 may have a plurality of bump structures.

The light-emitting structure 210 includes a first semiconductor pattern 212 of a first conductivity type, a light-emitting pattern 214, and a second semiconductor pattern 216 of a second conductivity type, which are stacked in order on the substrate 205.

Although not illustrated, a buffer layer may be additionally formed between the light-emitting structure 210 and the substrate 205. Any material that can act as a seed layer to form the light-emitting structure 210 may be applied as the buffer layer, such as, for example, InxAlyGa(1-x-y)N(0≦x≦1, 0≦y≦1), SixCyN(1-x-y)(0≦x≦1, 0≦y≦1).

The second semiconductor pattern 216, the light-emitting pattern 214 and the first semiconductor pattern 212 may include InxAlyGa(1-x-y)N(0≦x≦1, 0≦y≦1) (that is, a variety of GaN-containing materials). That is, the second semiconductor pattern 216, the light-emitting pattern 214 and the first semiconductor pattern 212 may be, for example, GaN, or AlGaN, or InGaN, or AlInGaN.

To specifically describe the respective layers, the first semiconductor pattern 212 may be the first conductivity type (e.g., n-type), and the second semiconductor pattern 216 may be the second conductivity type (e.g., p-type), although the first semiconductor pattern 212 may be the second conductivity type (p-type) and the second semiconductor pattern 216 is the first conductivity type (n-type), depending on the manner of design.

The light-emitting pattern 214 is a region where the carriers (e.g., electrons) of the first semiconductor pattern 212 and the carriers (e.g., holes) of the second semiconductor pattern 216 combine and generate light. Although not specifically illustrated, the light-emitting pattern 214 may be formed of a well layer and a barrier layer, in which the well layer has a smaller band gap than the barrier layer and thus the carriers (electrons, holes) gather and combine at the well layer. Depending on the number of well layers, such light-emitting pattern 214 may be categorized into a single quantum well (SQW) structure and a multiple quantum well (MQW) structure. The SQW structure includes one single well layer, while the MQW structure includes a multilayer of well layers. In order to adjust light-emitting characteristic, at least one of B, P, Si, Mg, Zn or Se may be doped on at least one place among the well layer and the barrier layer.

The first electrode 230 may be electrically connected with the first semiconductor pattern 212 of the first conductivity type, and the second electrode 220 may be electrically connected with the second semiconductor pattern 216 of the second conductivity type.

The first electrode 230 and the second electrode 220 may be configured as a single layer, or multilayer structure of conductive material. For example, the first electrode 230 and the second electrode 220 may each include at least one of materials such as silver (Ag), gold (Au), copper (Cu), zinc (Zn), aluminum (Al), indium (In), titanium (Ti), tin (Sn), magnesium (Mg), nickel (Ni), tungsten (W), platinum (Pt), chromium (Cr), tantalum (Ta), ruthenium (Ru), rhodium (Rh), iridium (Jr), palladium (Pd), and so on, or alloy thereof.

Alternatively, the first electrode 230 and the second electrode 220 may include a transparent conductive material. For example, the first electrode 230 and the second electrode 220 may each include one or more of indium tin oxide (ITO), aluminum zinc oxide (AZO), indium zinc oxide (IZO), ZnO, GZO (ZnO:Ga), In₂O₃, SnO₂, CdO, CdSnO₄, or Ga₂O₃.

The light-emitting element 200 used for the light-emitting package 10 according to some exemplary embodiments may be a flip chip type.

Further, although it is described herein that the light-emitting element 200 includes a light-emitting structure containing a gallium nitride semiconductor, the exemplary embodiments are not limited thereto. The light-emitting element 200 may include a light-emitting structure containing AlInGaP or AlInGaAs semiconductor.

The light-emitting element 200 may include an upper surface 200u and a sidewall 200s. When the light-emitting structure 210 is formed on one surface of the substrate 205, then the upper surface 200u of the light-emitting element 200 may be the other surface of the substrate 205 that is opposite to the one surface of the substrate 205. The sidewall 200s of the light-emitting element 200 may include a sidewall of the substrate 205 and the sidewall of the light-emitting structure 210.

To explain the manner how the light-emitting element 200 is connected with the light-emitting element mounting substrate 100, the first electrode 230 may be connected with the first wire 120 through a first conductive connector 241, for example, and the second electrode 220 may be connected with the second wire 130 through a second conductive connector 242, for example.

The first fluorescent layer 310 may be formed on the upper surface 200u of the light-emitting element 200. The first fluorescent layer 310 may be formed conformally on the upper surface 200u of the light-emitting element 200.

The first fluorescent layer 310 may be a film type, for example. That is, the first fluorescent layer 310 may be a fluorescent film fabricated in a film shape.

The width of the first fluorescent layer 310 in the first direction X and the width of the first fluorescent layer 310 in the second direction Y may be substantially identical to the widths of the light-emitting element mounting substrate 100 in the first direction X and in the second direction Y, respectively.

The second fluorescent layer 320 may be formed on the sidewall 200s of the light-emitting element 200. The second fluorescent layer 320 may surround the sidewall 200s of the light-emitting element 200.

As illustrated, the upper surface of the second fluorescent layer 320 and the upper surface 200u of the light-emitting element may form a same plane, although exemplary embodiments are not limited thereto. Accordingly, a portion of the sidewall 200s of the light-emitting element 200 may be surrounded by the second fluorescent layer 320, while the first fluorescent layer 310 may surround the rest of the sidewall 200s of the light-emitting element 200.

Alternatively, the second fluorescent layer 320 may be formed on the upper surface of the light-emitting element 200. In this case, the first fluorescent layer 310 may be formed on the upper surface 200u of the light-emitting element 200 where the second fluorescent layer 320 is formed.

The first fluorescent layer 310 may include a first transparent resin 312 and a first phosphor 314, and the second fluorescent layer 320 may include a second transparent resin 322 and a second phosphor 324.

When the light-emitting element 200 emits blue wavelength light, the first and the second phosphors 314, 324 may include a yellow phosphor, and may also include a red phosphor to increase color rendering index (CRI) characteristic. Alternatively, when the light-emitting element 200 emits ultra-violet (UV) wavelength light, the first and the second phosphors 314, 324 may include all of the red, green and blue (RGB).

The first transparent resin 312 is not limited to any specific material, as long as the material can stably disperse the first phosphor 374 and can be processed into a film shape. The second transparent resin 322 is not limited to any specific material, as long as it can stably disperse the second phosphor 324. The first transparent resin 312 and the second transparent resin 322 may each use a resin such as, for example, epoxy resin, silicone resin, rigid silicone resin, modified silicone resin, urethane resin, oxetane resin, acrylic resin, polycarbonate resin, polyimide resin, and so on.

Any material may be used as the first phosphor 314 and the second phosphor 324, as long as it absorbs light from the light-emitting element 200 and converts it into different wavelength light. For example, it may preferably, but not necessarily, be at least one or more selected from among nitride-/oxynitride-based phosphor, mainly activated by the lanthanoid element such as Eu, Ce, etc., alkaline earth halogen apatite phosphor mainly activated by lanthanoid element such as Eu, etc., or by transition metal element such as Mn, etc., alkaline earth metal borate halogen phosphor, alkaline earth metal aluminate phosphor, alkaline earth silicate, alkaline earth sulfide, alkaline earth thiogallate, alkaline earth silicon nitride, germanate, or rare earth aluminate mainly activated by lanthanoid element such as Ce, etc., rare earth silicate or organic and organic complex mainly activated by lanthanoid element such as Eu, etc., among others. More specific example may include the phosphors below, but not limited thereto.

The example may include nitride phosphor mainly activated by lanthanoid element such as Eu, Ce, etc. such as, M2Si5N8:Eu (M is at least one selected from among Sr, Ca, Ba, Mg, Zn), among others. Additionally, the example may include M2Si5N8:Eu, MSi7N10:Eu, M1.8Si5O0.2N8:Eu, M0.9Si7O0.1N10:Eu (M is at least one selected from among Sr, Ca, Ba, Mg, Zn), among others.

The example may include oxynitride phosphor mainly activated by lanthanoid element such as Eu, Ce, etc., such as, MSi2O2N2:Eu (M is at least one selected from among Sr, Ca, Ba, Mg, Zn), among others.

The example may include alkaline earth halogen apatite phosphor mainly activated by lanthanoid element such as Eu, etc., and by transition metal element such as Mn, etc., such as, M5(PO4)3 X:R (M is at least one selected from among Eu, Mn, Eu, X is at least one selected from among F, Cl, Br, I, R is at least one selected from among Eu, Mn, Eu), among others.

The example may include alkaline earth metal borate halogen phosphor such as M2B5O9X:R (M is at least one selected from among Sr, Ca, Ba, Mg, Zn, X is at least one selected from among F, Cl, Br, I, and R is at least one selected from among Eu, Mn, Eu), among others.

The example may include alkaline earth metal aluminate phosphor, such as, SrAl2O4:R, Sr4Al14O25:R, CaAl2O4:R, BaMg2Al16O27:R, BaMg2Al16O12:R, BaMgAl10O17:R (R is any one selected from among Eu, Mn, Eu).

The example may include alkaline earth sulfide phosphor, such as, La2O2S:Eu, Y2O2S:Eu, Gd2O2S:Eu, among others.

The example may include rare earth aluminate phosphor mainly activated by lanthanoid element such as Ce, etc., such as, YAG phosphor expressed by compositions of Y3Al5O12:Ce, (Y0.8Gd0.2)3Al5O12:Ce, Y3(Al0.8Ga0.2)5 O12:Ce, (Y, Gd)3 (Al, Ga)5 O12, among others. Additionally, the example may include Tb3Al5O12:Ce, Lu3Al5O12:Ce, among others, in which Y is partly or entirely substituted with Tb, Lu, etc.

The example may include alkaline earth silicate phosphor consisting of silicate, such as, (SrBa)2SiO4:Eu phosphor for a representative example, among others.

The example may include other phosphors such as ZnS:Eu, Zn2GeO4:Mn, MGa2S4:Eu (M is at least one selected from among Sr, Ca, Ba, Mg, Zn, X is at least one selected from among F, Cl, Br, I), among others.

As desired, the phosphors mentioned above may contain one or more selected from among Tb, Cu, Ag, Au, Cr, Nd, Dy, Co, Ni, Ti, in place for, or in addition to Eu.

Further, beside the phosphors mentioned above, the first phosphor 314 and the second phosphor 324 may use other phosphors with the same performance and effect.

The first phosphor 314 included in the first fluorescent layer 310 and the second phosphor 324 included in the second fluorescent layer 320 may have different materials or compositions. Alternatively, the first phosphor 314 included in the first fluorescent layer 310 and the second phosphor 324 included in the second fluorescent layer 320 may have the same materials or compositions.

In the light-emitting package 10 according to some exemplary embodiments, a lens may not be formed on the first fluorescent layer 310. That is, the light-emitting package 10 may not include the lens. In such case, the light-emitting package 10 may have reduced size.

Additionally, a fabricating method of a light-emitting package according to some exemplary embodiments will be explained with reference to FIGS. 5 and 6.

The light-emitting element 200 is mounted on the light-emitting element mounting substrate 100. The light-emitting element 200 is connected with the light-emitting element mounting substrate 100 by the first conductive connector 241 and the second conductive connector 242.

The second fluorescent layer 320 surrounding the sidewall 200s of the light-emitting element 200 is then formed on the light-emitting element mounting substrate 100.

Next, the film-type first fluorescent layer 310 is formed on the second fluorescent layer 320 and the upper surface 200u of the light-emitting element 200.

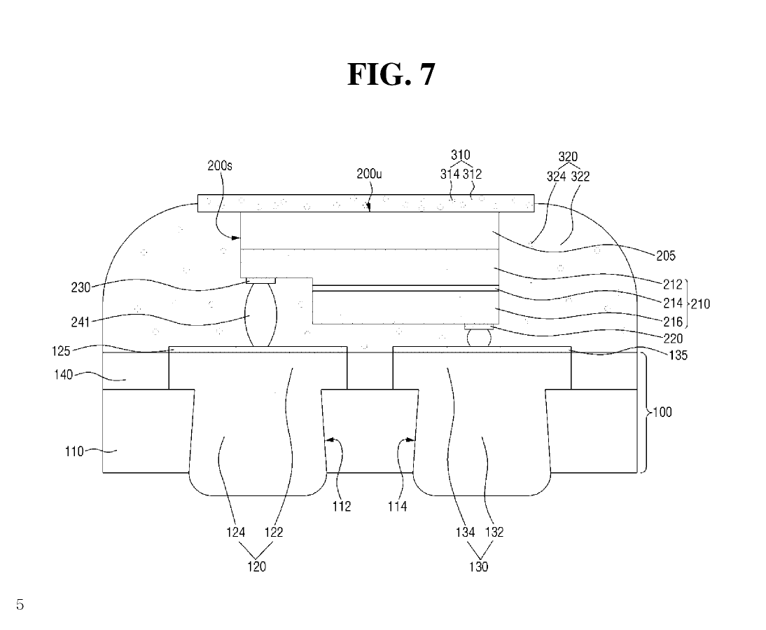

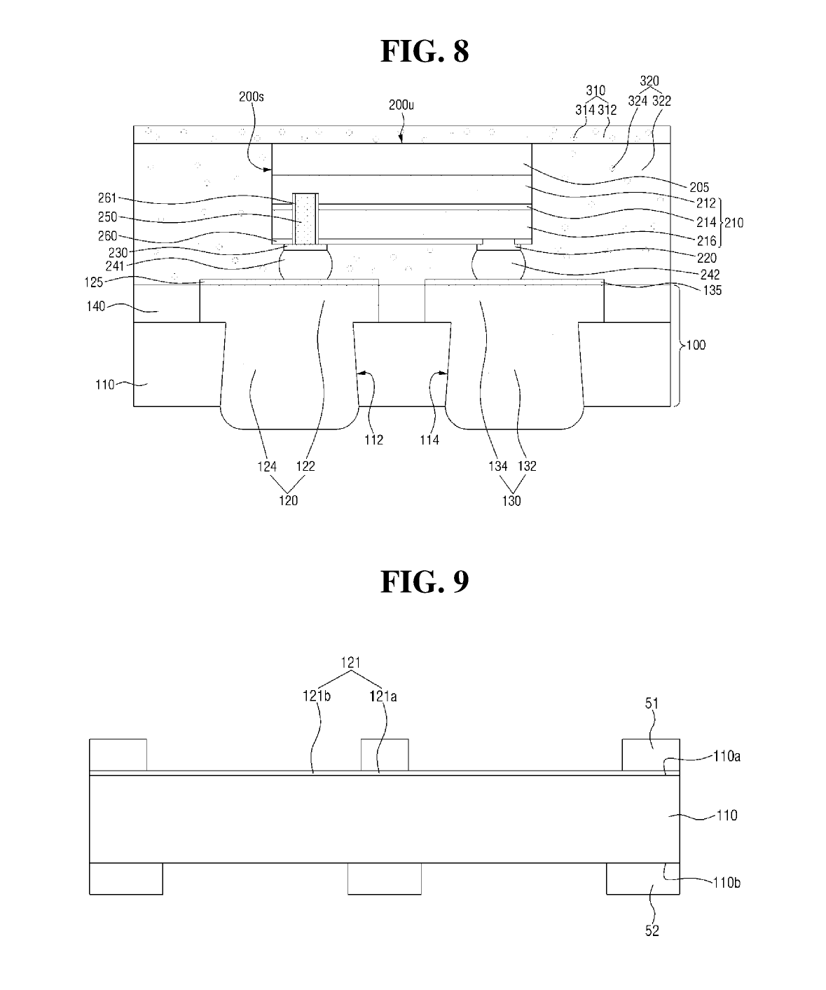

FIG. 7 is a view provided to explain a light-emitting package according to some exemplary embodiments. FIG. 8 is a view provided to explain a light-emitting package according to some exemplary embodiments. For convenience of explanation, differences from the exemplary embodiments explained above with reference to FIGS. 5 and 6 will be mainly explained below.

Referring to FIG. 7, in the light-emitting package 10 according to some exemplary embodiments, the width of the first fluorescent layer 310 in the first direction X and the width of the first fluorescent layer 310 in the second direction Y are smaller than the widths of the light-emitting element mounting substrate 100 in the first direction X and in the second direction Y, respectively.

The first fluorescent layer 310 may be adjoined with the upper surface 200u of the light-emitting element 200. That is, no other fluorescent layer may be interposed between the first fluorescent layer 310 and the substrate 205.

The upper surface of the second fluorescent layer 320 is not laid in the same plane as the upper surface 200u of the light-emitting element 200.

Referring to FIGS. 5 and 7, a fabricating method of a light-emitting package according to some exemplary embodiments will be explained.

The light-emitting element 200 is mounted on the light-emitting element mounting substrate 100. The light-emitting element 200 is connected with the light-emitting element mounting substrate 100 by the first conductive connector 241 and the second conductive connector 242.

Next, the film-type first fluorescent layer 310 is formed on the upper surface 200u of the light-emitting element 200.

The second fluorescent layer 320 surrounding the sidewall 200s of the light-emitting element 200 is then formed on the light-emitting element mounting substrate 100. The second fluorescent layer 320 is formed by filling a space between the first fluorescent layer 310 and the light-emitting element mounting substrate 100.

Referring to FIG. 8, in the light-emitting package 10 according to some exemplary embodiments, the light-emitting element 200 may include a through via contact 250.

The through via contact 250 may extend from the first semiconductor pattern 212 of the first conductivity type to the first electrode 230. The through via contact 250 may connect the first semiconductor pattern 212 and the first electrode 230.

The light-emitting element 200 may include a first insulating pattern 260, formed on the second semiconductor pattern 216 of the second conductivity type, and a second insulating pattern 261.

The first electrode 230 and the second electrode 220 may be formed on the first insulating pattern 260. The first insulating pattern 260 prevents electric connection between the first electrode 230 and the second semiconductor pattern 216.

The second insulating pattern 261 may be formed on the sidewall of the through via contact 250. The second insulating pattern 261 prevents electric connection between the through via contact 250 and the light-emitting pattern 214, and between the through via contact 250 and the second semiconductor pattern 216.

FIGS. 9 to 14 are views illustrating intermediate stages of fabrication, provided to explain a fabricating method of a light-emitting element mounting substrate according to some exemplary embodiments.

While a fabricating method of one single light-emitting element mounting substrate is described with reference to FIGS. 9 to 14, exemplary embodiments are not limited thereto. Accordingly, considering possibility that a plurality of light-emitting element mounting substrates are fabricated first and then divided into each, it is of course possible that the fabricating method described with reference to FIGS. 9 to 14 is applicable to forming of a plurality of light-emitting element mounting substrates.

Referring to FIG. 9, a plating seed layer 121 is formed on the first surface 110a of the insulative base plate 110.

The insulative base plate 110 includes the first surface 110a and the second surface 110b opposed to each other. The insulative base plate 110 may be a single layer.

The plating seed layer 121 is not formed on the second surface 110b of the insulative base plate 110. The plating seed layer 121 may contact the insulative base plate 110.

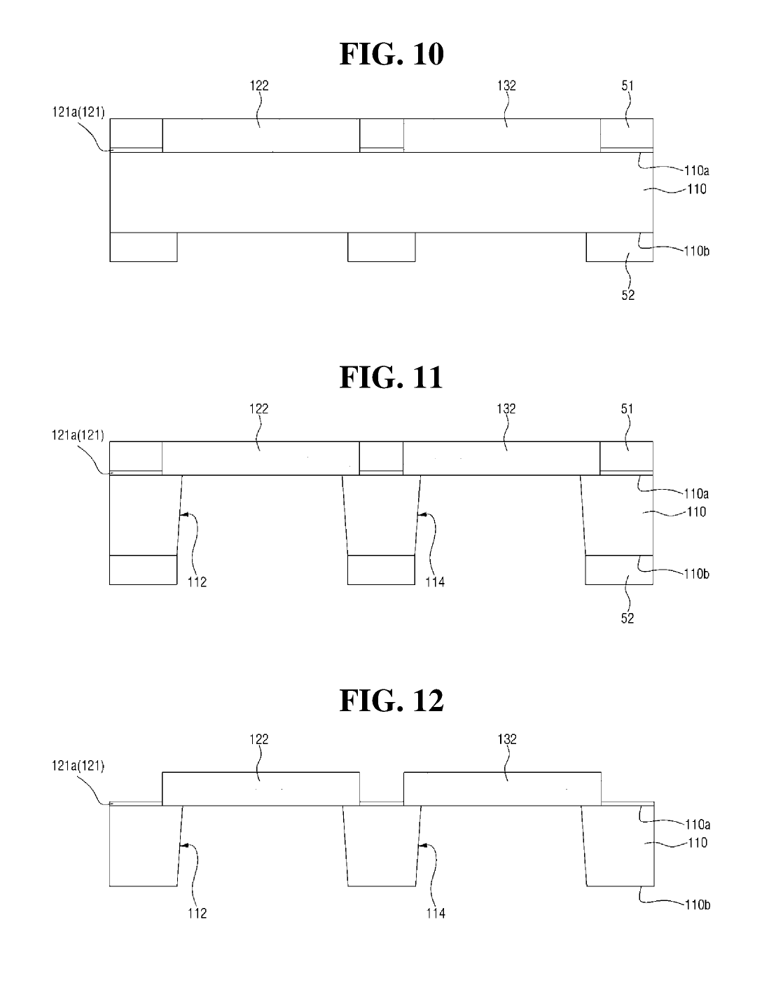

The plating seed layer 121 includes a first portion 121a and a second portion 121b. The second portion 121b of the plating seed layer is where the first and the second conductive pads (122, 132 in FIG. 10) are formed later, and the first portion 121a of the plating seed layer is the portion that separates the first and the second conductive pads 122, 132.

The plating seed layer 121 may include copper or copper alloy, for example.

A first mask pattern 51 is then formed on the first surface 110a of the insulative base plate 110. Further, a second mask pattern 52 is formed on the second surface 110b of the insulative base plate 110.

The first mask pattern 51 is formed on the first portion 121a of the plating seed layer. Accordingly, the second portion 121b of the plating seed layer is exposed by the first mask pattern 51.

Referring to FIG. 10, using the first mask pattern 51, the first conductive pad 122 and the second conductive pad 132 are formed on the first surface 110a of the insulative base plate 110.

More specifically, the first conductive pad 122 and the second conductive pad 132 are formed on the second portion 121b of the plating seed layer exposed by the first mask pattern 51. The first conductive pad 122 and the second conductive pad 132 may be formed with a plating method, for example.

The first conductive pad 122 and the second conductive pad 132 may include copper or copper alloy, for example.

The second portion 121b of the plating seed layer may become a part of the first conductive pad 122 and a part of the second conductive pad 132.

Referring to FIG. 11, the first through hole 112 and the second through hole 114 are formed in the insulative base plate 110. The first through hole 112 and the second through hole 114 are formed by using the second mask pattern 52 as a mask.

The first through hole 112 and the second through hole 114 formed in the insulative base plate 110 each extend from the second surface 110b of the insulative base plate 110 to the first surface 110a of the insulative base plate 110.

A portion of the first conductive pad 122 and a portion of the second conductive pad 132 are exposed by the first through hole 112 and the second through hole 114.

Referring to FIG. 12, the first mask pattern 51 and the second mask pattern 52 are removed.

By the removal of the first mask pattern 51 and the second mask pattern 52, the first portion 121a of the plating seed layer and the second surface 110b of the insulative base plate 110 may be exposed.

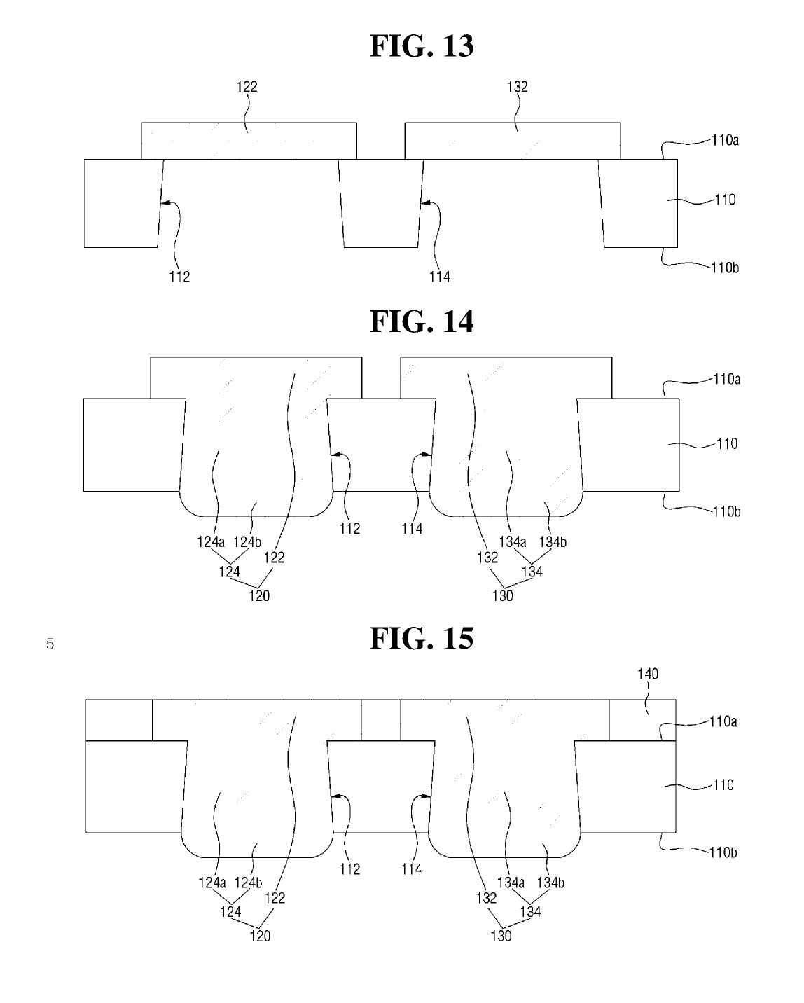

Referring to FIG. 13, the first portion 121a of the plating seed layer exposed by the removal of the first mask pattern 51 is removed.

By the removal of the first portion 121a of the plating seed layer, the first surface 110a of the insulative base plate 110 may be exposed.

Referring to FIG. 14, the first through conduit 124 filling the first through hole 112, and the second through conduit 134 filling the second through hole 114 are formed.

The first through hole 112 and the second through hole 114 each expose the first conductive pad 122 and the second conductive pad 132, and therefore, the first conductive pad 122 and the second conductive pad 132 as exposed may act as seed layers to form the first through conduit 124 and the second through conduit 134.

The first through conduit 124 and the second through conduit 134 may be formed with a plating method, for example. The first through conduit 124 and the second through conduit 134 may include copper (Cu) or copper alloy, for example.

The first through conduit 124 and the second through conduit 134 may be formed with the plating method, and therefore, the first through conduit 124 and the second through conduit 134 may each include portions 124b, 134b protruding farther than the second surface 110b of the insulative base plate 110, respectively.

As a result, the first wire 120 and the second wire 130 may be formed.

Next, referring to FIG. 2, the first conductive reflective film 125 is formed on the first conductive pad 122, and the second conductive reflective film 135 is formed on the second conductive pad 132.

The first conductive reflective film 125 and the second conductive reflective film 135 may each be formed by a plating method. Accordingly, the first conductive reflective film 125 may be formed on the upper surface 122u of the first conductive pad and on the sidewall 122s of the first conductive pad, and the second conductive reflective film 135 may be formed on the upper surface 132u of the second conductive pad and on the sidewall 132s of the second conductive pad.

Next, referring to FIG. 4, the insulative reflective pattern 140 may be formed on the first surface 110a of the insulative base plate 110 exposed by the removal of the first mask pattern 51.

The insulative reflective pattern 140 may surround the sidewall 122s of the first conductive pad and the sidewall 132s of the second conductive pad where the first conductive reflective film 125 and the second conductive reflective film 135 are formed.

FIG. 15 is a view illustrating intermediate stages of fabrication, provided to explain a fabricating method of a light-emitting element mounting substrate according to some exemplary embodiments.

For reference, FIG. 15 may be an illustration of stage performed after fabricating stage using FIG. 14. Accordingly, FIGS. 9 to 14 will not be redundantly described below.

Referring to FIG. 15, the insulative reflective pattern 140 may be formed on the first surface 110a of the insulative base plate 110 exposed by the removal of the first mask pattern 51.

The insulative reflective pattern 140 may be adjoined with the sidewall 122s of the first conductive pad and with the sidewall 132s of the second conductive pad.

Next, referring to FIG. 3, the first conductive reflective film 125 is formed on the upper surface 122u of the first conductive pad, and the second conductive reflective film 135 is formed on the upper surface 132u of the second conductive pad. The first conductive reflective film 125 does not extend between the first conductive pad 122 and the insulative reflective pattern 140, and the second conductive reflective film 135 does not extend between the second conductive pad 132 and the insulative reflective pattern 140.

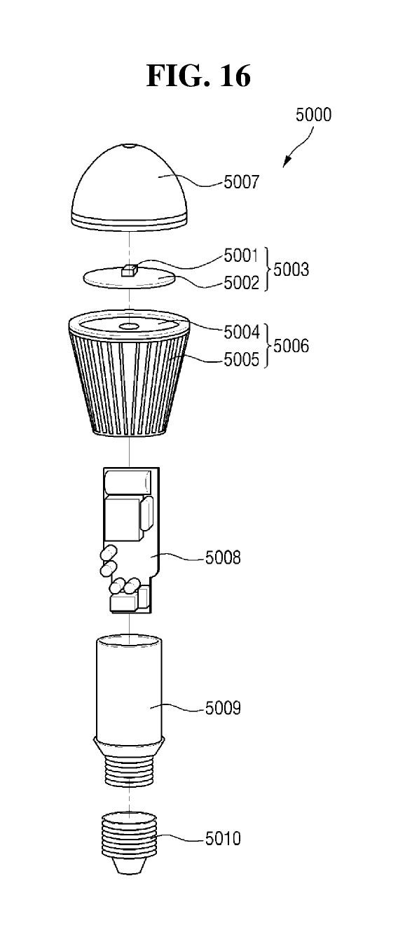

FIG. 16 explains an example of applying a light-emitting package to a lighting apparatus according to an exemplary embodiment.

Referring to FIG. 16, a lighting apparatus 5000 exemplified as a bulb-type lamp includes a light-emitting module 5003, a driving portion 5008 and an external connecting portion 5010. Further, external structures such as an external housing 5006, an internal housing 5009, a cover portion 5007, and so on, may be additionally included.

The light-emitting module 5003 may include, for example, a light-emitting package 5001 in the similar structure as illustrated in FIGS. 5 to 8, and a circuit board 5002 mounted with the light-emitting package 5001. According to an exemplary embodiment, it is exemplified that one light-emitting package 5001 is mounted on the circuit board 5002, although a plurality of light-emitting packages may be mounted as desired. Further, unlike the illustration, the light-emitting package 5001 may not be mounted on the circuit board 5002.

The external housing 5006 may act as a heat releasing portion, and may include a heat releasing plate 5004 to enhance heat dissipation effect through a direct contact with the light-emitting module 5003, and heat dissipation fins 5005 surrounding the side surface of the lighting apparatus 5000. The cover portion 5007 may be mounted on the light-emitting module 5003 in a convex lens shape. The driving portion 5008 may be mounted on the internal housing 5009 and connected to the external connecting portion 5010 such as a socket structure to receive power from an external power source.

Further, the driving portion 5008 operates to convert the power into electricity source suitable for driving the light-emitting package 5001 of the light-emitting module 5003 and provide the same. For example, such driving portion 5008 may be configured as an AC-DC converter or rectification circuit components.

Further, although not illustrated, the lighting apparatus 5000 may additionally include a communication module.

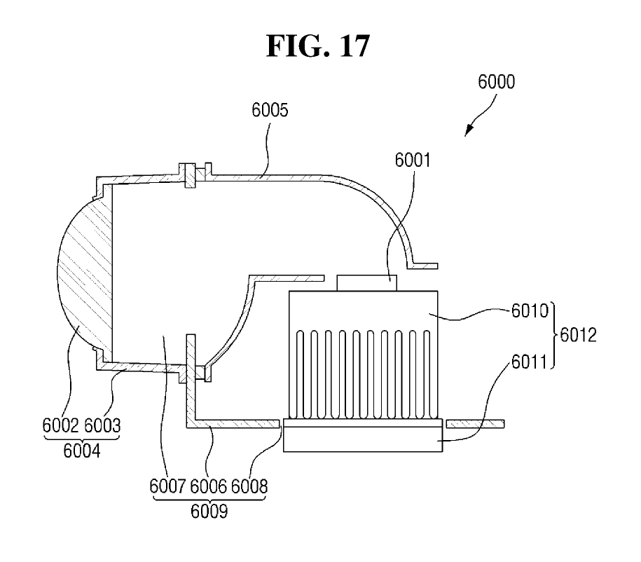

FIG. 17 represents an example of applying a semiconductor light-emitting element to a head lamp according to an exemplary embodiment.

Referring to FIG. 17, a head lamp 6000 used as a light of an automobile may include a light source 6001, a reflector 6005, and a lens cover 6004, in which the lens cover 6004 may include a hollow guide 6003 and a lens 6002. The light source 6001 may include at least any one of the light-emitting packages described with reference to FIGS. 5 to 8.

Further, the head lamp 6000 may additionally include a heat dissipator 6012 to release the heat generated from the light source 6001 to outside, in which the heat dissipator 6012 may include a heat sink 6010 and a cooling fan 6011 for effective heat dissipation.

Further, the head lamp 6000 may additionally include a housing 6009 to fixedly support the heat dissipator 6012 and the reflector 6005, and the housing 6009 may include a center hole 6008 so that the heat dissipator 6012 is combined with a body 6006 and one surface and mounted.

Further, the housing 6009 may include a front hole 6007 on the other surface which is integrally connected with the one surface and bent in a perpendicular direction. The reflector 6005 may be fixed to the housing 6009 so that the light generated from the light source 6001 is reflected to be passed through the front hole 6007 and emitted outside.

In concluding the detailed description, those skilled in the art will appreciate that many variations and modifications can be made to the exemplary embodiments without substantially departing from the principles of the inventive concept. Therefore, the disclosed exemplary embodiments are used in a generic and descriptive sense only and not for purposes of limitation.

What is claimed is:

1. A light-emitting element mounting substrate comprising:
an insulative base plate comprising a first surface and a second surface opposed to each other;
a first conductive pad formed on the first surface of the insulative base plate;
a second conductive pad formed on the first surface of the insulative base plate, and being separated from the first conductive pad;
a first through hole and a second through hole penetrating through the insulative base plate and being separated from each other;
a first through conduit filling the first through hole and being adjoined with the first conductive pad; and
a second through conduit filling the second through hole and being adjoined with the second conductive pad,
wherein, with reference to the first surface of the insulative base plate, a sum of an area of the first through conduit and an area of the second through conduit is between 20% and 80% of an area of the first surface of the insulative base plate.

2. The light-emitting element mounting substrate of claim 1, further comprising an insulative reflective pattern formed on the first surface and surrounding a sidewall of the first conductive pad and a sidewall of the second conductive pad.

3. The light-emitting element mounting substrate of claim 2, wherein the insulative reflective pattern includes a titanium dioxide (TiO₂).

4. The light-emitting element mounting substrate of claim 1, further comprising:
a first conductive reflective film on the first conductive pad; and
a second conductive reflective film on the second conductive pad.

5. The light-emitting element mounting substrate of claim 4, wherein the first conductive reflective film is formed on an upper surface and a sidewall of the first conductive pad, and the second conductive reflective film is formed on an upper surface and a sidewall of the second conductive pad.

6. The light-emitting element mounting substrate of claim 4, wherein the first conductive reflective film is formed on an upper surface of the first conductive pad, and is not formed on a sidewall of the first conductive pad, and
wherein the second conductive reflective film is formed on an upper surface of the second conductive pad, and is not formed on a sidewall of the second conductive pad.

7. The light-emitting element mounting substrate of claim 1, wherein the first conductive pad and the second conductive pad each include a portion extending along the first surface.

8. The light-emitting element mounting substrate of claim 1, wherein the first through conduit and the second through conduit each do not comprise a portion extending along the second surface.

9. The light-emitting element mounting substrate of claim 1, wherein the first through conduit and the second through conduit each include a first protrusion and a second protrusion protruding from the second surface, respectively, and
wherein a height of the first protrusion and a height of the second protrusion are smaller than a thickness of the insulative base plate.

10. A light-emitting element mounting substrate comprising:
an insulative base plate comprising a first through hole and a second through hole which are separated from each other;
an insulative reflective pattern formed on the insulative base plate, contacting the insulative base plate, and comprising a first opening and a second opening which are separated from each other;
a first wire comprising:
a first conductive pad filling the first opening; and
a first through conduit filling the first through hole; and
a second wire comprising:
a second conductive pad filling the second opening; and
a second through conduit filling the second through hole.

11. The light-emitting element mounting substrate of claim 10, wherein a width of the first conductive pad is greater than a width of the first through conduit, and a width of the second conductive pad is greater than a width of the second through conduit, and
wherein the first conductive pad entirely overlaps the first through conduit, and the second conductive pad entirely overlaps the second through conduit.

12. The light-emitting element mounting substrate of claim 10, further comprising:
a first conductive reflective film formed on an upper surface of the first conductive pad; and
a second conductive reflective film formed on an upper surface of the second conductive pad.

13. The light-emitting element mounting substrate of claim 12, wherein the first conductive reflective film extends on a sidewall of the first conductive pad, and the second conductive reflective film extends on a sidewall of the second conductive pad.

14. The light-emitting element mounting substrate of claim 10, wherein, with reference to the first surface of the insulative base plate, a sum of an area of the first through conduit and an area of the second through conduit is between 20% and 80% of an area of the insulative base plate.

15. The light-emitting element mounting substrate of claim 10, wherein the insulative reflective pattern comprises a titanium dioxide (TiO₂).

16. A light-emitting element mounting substrate comprising:
an insulative base plate comprising first and second through holes penetrating through the insulative base plate from top to bottom surfaces thereof; and
first and second conductive wires insulated from each other and respectively inserted in the first and second through holes of the insulative base plate,
wherein the first and second conductive wires are protruded from the top and bottom surfaces of the insulative base plate such that a thickness of the first and second wires is greater than a thickness of the insulative base plate,
wherein a width of each of the first and second conductive wires at a portion which is protruded from the top surface of the insulative base plate is greater than a width of each of the first and second conductive wires at a portion which is inserted in each of the first and second through holes, respectively, and
wherein each of the first and second conductive wires does not include a portion extending along the bottom surface.

17. The light-emitting element mounting substrate of claim 16, wherein the width of each of the first and second conductive wires at the portion which is protruded from the top surface of the insulative base plate is greater than a width of each of the first and second conductive wires at a portion which is protruded from the bottom surface of the insulative base plate, respectively.

18. The light-emitting element mounting substrate of claim 16, wherein each of the first and second through holes has a greater width at the bottom surface of the insulative base plate than the top surface of the insulative base plate.

19. The light-emitting element mounting substrate of claim 16, wherein side surfaces of the first and second conductive wires protruded from the top surface of the insulative base plate are encompassed by an insulative reflective pattern comprising a titanium dioxide (TiO₂).

20. The light-emitting element mounting substrate of claim 16, wherein top surfaces of the first and second conductive wires protruded from the top surface of the insulative base plate are coated by first and second conductive reflective films, respectively, and
wherein each of the first and second conductive reflective films comprises at least one aluminum (Al), silver (Ag), palladium (Pd), rhodium (Rh), and platinum (Pt).
